(19) United States
(12) Patent Application Publication
(10) Pub. No.: US 2026/0026216 A1
(43) Pub. Date: Jan. 22, 2026

(54) Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Hongjun Zhou, Beijing (CN); Fan He, Beijing (CN); Taofeng Xie, Beijing (CN)

(21) Appl. No.: 18/862,011

(22) PCT Filed: Aug. 14, 2024
(86) PCT No.: PCT/CN2024/112167

§ 371 Date: Oct. 31, 2024

(30) Foreign Application Priority Data
Sep. 28, 2023 (CN) 202311285152.6

(51) Int. Cl. H10K 59/131

(52) U.S. Cl. CPC H10K 59/131

(57) ABSTRACT

A display panel includes first data lines, second data lines, first connection lines, second connection lines, first power auxiliary lines, a first power bus line and a first power fan-out line. A first end of a first connection line is connected to a first data line, and a second end of the first connection line extends to a central region. A first end of a second connection line is connected to the second end of the first connection line, and a second end of the second connection line extends to an edge of the display region close to a fan-out region. A first power auxiliary line includes at least one current confluence point connected to the first power bus. In a first direction, the at least one current confluence point is closer to the central region in the first direction than a first sidewall of a contact portion.

### CROSS-REFERENCE TO RELATED APPLICATIONS

This application is the United States national phase of International Patent Application No. PCT/CN2024/112167, filed Aug. 14, 2024, and claims priority to Chinese Patent Application No. 202311285152.6, filed Sep. 28, 2023, the disclosures of which are hereby incorporated by reference in their entireties.

### BACKGROUND OF THE INVENTION

### Field of the Invention

The present disclosure relates to the field of display technologies, and in particular, to a display panel and a display apparatus.

### Description of Related Art

Organic light-emitting diode (OLED) display apparatuses have gradually become one of the mainstream products in the display field due to their excellent properties such as self-luminescence, no need for backlight, high contrast, small thickness, wide viewing angle, fast response, being used for flexible panels, wide operating temperature range, simple structure and process. OLED display panels can be widely used in terminal products such as smart phones, tablet computers, TVs and wearable devices (e.g. watches). High Pixels per Inch (PPI) and narrow bezel are currently an important development direction of OLED display apparatuses.

### SUMMARY OF THE INVENTION

In an aspect, a display panel is provided. The display panel has a display region and a fan-out region, and the fan-out region is adjacent to an edge of the display region. The display panel includes a plurality of data lines, a plurality of first connection lines, a plurality of second connection lines, a plurality of first power auxiliary lines, a first power bus and a first power fan-out line. The plurality of data lines are arranged at intervals in a first direction, and the plurality of data lines extend in a second direction, the second direction and the first direction intersecting. The plurality of data lines include a plurality of first data lines and a plurality of second data lines, the plurality of first data lines are located in two edge regions of the display region in the first direction, and the plurality of second data lines are located in a central region of the display region in the first direction. The plurality of first connection lines extend in the first direction. A first end of a first connection line is connected to a first data line, and a second end of the first connection line extends to the central region of the display region in the first direction. The plurality of second connection lines extend in the second direction. A first end of a second connection line is connected to the second end of the first connection line, and a second end of the second connection line extends to an edge of the display region close to the fan-out region. The plurality of first power auxiliary lines are located on a side of the plurality of second connection lines close to the plurality of first data lines, the plurality of first power auxiliary lines are arranged at intervals in the first direction, and the plurality of first power auxiliary lines extend in the second direction. The first power bus extends in the first direction and is connected to the plurality of first power auxiliary lines. The first power fan-out line is located on a side of the first power bus away from the display region. The first power fan-out line includes a contact portion, the contact portion is in contact with and connected to the first power bus, and the contact portion includes a first sidewall close to an edge region of the display region in the first direction. A first power auxiliary line includes at least one current confluence point connected to the first power bus. In the first direction, the at least one current confluence point is closer to the central region of the display region in the first direction than the first sidewall.

In some embodiments, the first power auxiliary line includes a current confluence point connected to the first power bus, and an end of the first power auxiliary line close to the fan-out region is electrically connected to the first power bus to form the current confluence point; the first power bus includes a first extension section and a second extension section; in the second direction, the first extension section is arranged opposite to a region where the plurality of first power auxiliary lines are located, and the second extension section is arranged opposite to a region where at least part of the plurality of second connection lines are located; and at least part of the contact portion is in contact with and connected to the first extension section.

In some embodiments, the contact portion includes a first sub-portion and a second sub-portion. The first sub-portion is in contact with and connected to the second extension section, and the first sub-portion and the first extension section are spaced apart. The second sub-portion and the first sub-portion are spaced apart in the first direction. The second sub-portion is located on a side of the first sub-portion away from the central region of the display region in the first direction, a part of the second sub-portion is in contact with and connected to the first extension section, and another part of the second sub-portion is in contact with and connected to the second extension section.

In some embodiments, the contact portion includes a first sub-portion and a second sub-portion. The first sub-portion is in contact with and connected to the second extension section, and the first sub-portion and the first extension section are spaced apart. The second sub-portion and the first sub-portion are spaced apart in the first direction, and the second sub-portion is located on a side of the first sub-portion away from the central region of the display region in the first direction; and the second sub-portion is in contact with and connected to the first extension section.

In some embodiments, a sidewall of the second sub-portion close to the first sub-portion is flush with a first reference line; or the sidewall of the second sub-portion close to the first sub-portion is located on a side of the first reference line away from the second sub-portion. The first reference line coincides with one of the plurality of first power auxiliary lines that is closest to the central region of the display region in the first direction.

In some embodiments, the contact portion includes a first sub-portion and a second sub-portion. A part of the first sub-portion is in contact with and connected to the first extension section, and another part of the first sub-portion is in contact with and connected to the second extension section. The second sub-portion and the first sub-portion are spaced apart in the first direction, and the second sub-portion is located on a side of the first sub-portion away from the central region of the display region in the first direction; and the second sub-portion is in contact with and connected to the first extension section.

In some embodiments, the contact portion includes a first sub-portion and a second sub-portion. The first sub-portion is in contact with and connected to the first extension section. The second sub-portion and the first sub-portion are spaced apart in the first direction, and the second sub-portion is located on a side of the first sub-portion away from the central region of the display region in the first direction; and the second sub-portion is in contact with and connected to the first extension section.

In some embodiments, a sidewall of the first sub-portion close to the central region of the display region in the first direction is flush with a first reference line, or is located on a side of the first reference line away from the central region of the display region in the first direction; and the first reference line coincides with one of the plurality of first power auxiliary lines that is closest to the central region of the display region in the first direction.

In some embodiments, the display panel further includes at least one second power auxiliary line and at least one third connection line. The at least one second power auxiliary line extends in the second direction, a second power auxiliary line is located between two adjacent second connection lines, and an end of the second power auxiliary line close to the fan-out region is connected to the first power bus. An end of a third connection line is connected to the first power auxiliary line, and another end of the third connection line is connected to a second power auxiliary line. An end of the first power auxiliary line close to the fan-out region is connected to the first power bus to form a current confluence point; and at least one first power auxiliary line is connected to the first power bus through a third connection line and a second power auxiliary line in sequence, to form a current confluence point.

In some embodiments, the first power bus includes a first extension section and a second extension section; in the second direction, the first extension section is arranged opposite to a region where the plurality of first power auxiliary lines are located, and the second extension section is arranged opposite to a region where the at least one second power auxiliary line and at least part of the plurality of second connection lines are located; and at least part of the contact portion is connected to the second extension section.

In some embodiments, the contact portion is in contact with and connected to the second extension section; in the first direction, the first sidewall is closer to the central region of the display region in the first direction than the plurality of first power auxiliary lines; the contact portion further includes a second sidewall close to the central region of the display region in the first direction; the second sidewall is flush with a second power auxiliary line closest to the central region of the display region in the first direction, or the second sidewall is closer to the first sidewall than the second power auxiliary line closest to the central region of the display region in the first direction.

In some embodiments, the contact portion includes a first sub-portion and a second sub-portion. At least part of the first sub-portion is in contact with and connected to the second extension section. The second sub-portion and the first sub-portion are spaced apart in the first direction, the second sub-portion is located on a side of the first sub-portion away from the central region of the display region in the first direction, and at least part of the second sub-portion is in contact with and connected to the first extension section.

In some embodiments, the display panel includes plurality of second power auxiliary lines, and a number of second connection lines arranged between two adjacent second power auxiliary lines is in a range of 2 to 7, inclusive.

In some embodiments, the first sub-portion and the second sub-portion extend in the second direction, and a first end of the first sub-portion and a first end of the second sub-portion are both connected to the first power bus; the first power fan-out line further includes a bonding portion extending in the first direction, and two ends of the bonding portion are respectively connected to a second end of the first sub-portion and a second end of the second sub-portion.

In some embodiments, a size of the second sub-portion in the first direction is greater than a size of the first sub-portion in the first direction.

In some embodiments, the size of the first sub-portion in the first direction is D1; the size of the second sub-portion in the first direction is D2; and D1 and D2 satisfy: D2=(1.2˜4)×D1.

In some embodiments, the first power auxiliary line includes a third extension section and a fourth extension section. The third extension section is connected to the first power bus. The fourth extension section is located on a side of the third extension section away from the fan-out region and connected to the third extension section. A size of the third extension section in the first direction is greater than a size of the fourth extension section in the first direction.

In some embodiments, the size of the third extension section in the first direction is D3; the size of the fourth extension section in the first direction is D4; and D3 and D4 satisfy: D3=(2˜5)×D4.

In some embodiments, the first power bus includes a first sub-line and two second sub-lines. The first sub-line extends along a border of the fan-out region close to the display region and is electrically connected to the plurality of first power auxiliary lines. The two second sub-lines are at least partially located on a side of the first sub-line away from the display region and are electrically connected to the first sub-line. The two second sub-lines are spaced apart in the first direction; the two second sub-lines are respectively located in two edge regions of the fan-out region in the first direction; and a second sub-line is electrically connected to the first power fan-out line.

In another aspect, a display apparatus is provided. The display apparatus includes a driver circuit board and the display panel as described in any one of the above embodiments. The driver circuit board is configured to transmit control signals to the display panel.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of another display apparatus, in accordance with some embodiments;

FIG. 3 is a sectional view showing a structure of a display panel, in accordance with some embodiments;

FIG. 4 is a plan view showing a structure of a display panel, in accordance with some embodiments;

FIG. 5 is a partial enlarged view of the region A in FIG. 4;

FIG. 6 is a structural diagram of a display panel, in accordance with some embodiments;

FIG. 7 is a structural diagram of another display panel, in accordance with some embodiments;

FIG. 8 is a structural diagram of yet another display panel, in accordance with some embodiments;

FIG. 9 is a structural diagram of yet another display panel, in accordance with some embodiments;

FIG. 10 is a structural diagram of yet another display panel, in accordance with some embodiments;

FIG. 11 is a structural diagram of yet another display panel, in accordance with some embodiments;

FIG. 12 is a structural diagram of yet another display panel, in accordance with some embodiments;

FIG. 13 is a structural diagram of yet another display panel, in accordance with some embodiments;

FIG. 14 is a structural diagram of yet another display panel, in accordance with some embodiments;

FIG. 15 is a structural diagram of yet another display panel, in accordance with some embodiments;

FIG. 16 is a structural diagram of yet another display panel, in accordance with some embodiments;

FIG. 17 is a structural diagram of yet another display panel, in accordance with some embodiments;

FIG. 18 is a structural diagram of yet another display panel, in accordance with some embodiments; and

FIG. 19 is a partial enlarged view of a first power auxiliary line of a display panel, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, terms such as “first” and “second” are only used for descriptive purposes, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

In the description of some embodiments, the terms such as “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The phrase “applicable to” or “configured to” as used herein indicates an open and inclusive expression, which does not exclude apparatuses that are applicable to or configured to perform additional tasks or steps.

In addition, the use of the phrase “based on” or “according to” is meant to be open and inclusive, since a process, step, calculation or other action that is “based on” or “according to” one or more of the stated conditions or values may, in practice, be based on or according to additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of regions in a device, and are not intended to limit the scope of the exemplary embodiments.

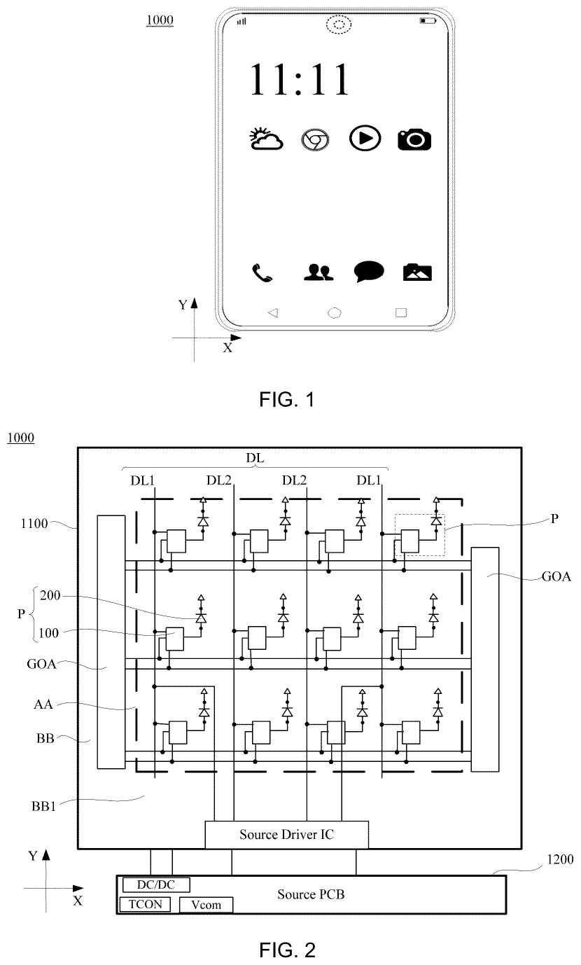

FIG. 1 is a structural diagram of a display apparatus according to some embodiments.

Referring to FIG. 1, the embodiments of the present disclosure provide a display apparatus 1000. The display apparatus 1000 is a product having an image display function. For example, the display apparatus 1000 may be any apparatus that displays images whether in motion (e.g., videos) or stationary (e.g., still images), and whether textual or graphical.

For example, the display apparatus 1000 may be any product or component having a display function, such as a television, a notebook computer, a tablet computer, a personal digital assistant (PDA), a mobile phone (cellphone), a watch, a clock, a calculator, GPS receiver/navigator, a camera, a display of camera views (e.g., a display of a rear-view camera in a vehicle), a wearable device, an augmented reality (AR) device, a virtual reality (VR) device, a vehicle-mounted display, or a flight display. For example, as shown in FIG. 1, the display apparatus 1000 may be a mobile phone.

From the perspective of the light emission type of the display apparatus 1000, the display apparatus 1000 may be an organic light-emitting diode display apparatus, a quantum dot electroluminescent display apparatus (quantum dot light-emitting diode (QLED)), or a mini/micro light-emitting diode (MLED). From the perspective of the form of the display apparatus 1000, the display apparatus 1000 may be a flat display apparatus, a curved display apparatus, or a foldable display apparatus. From the perspective of the shape of the display apparatus 1000, the display apparatus 1000 may be rectangular or circular. The embodiments of the present disclosure are not specifically limited thereto. Some embodiments of the present disclosure are schematically described below by taking an example in which the display apparatus is rectangular and is a flat OLED display apparatus. However, the embodiments of the present disclosure are not limited thereto, and any other display apparatuses may also be considered as long as the same technical concept is applied.

FIG. 2 is a structural diagram of a display apparatus according to some other embodiments.

In some embodiments, the display apparatus 1000 includes a display panel 1100 and a driver circuit board 1200. The driver circuit board 1200 may include, for example, a timing controller (TCON), a power management chip DC/DC, an adjustable resistor voltage divider circuit (generating Vcom) and other driver circuits. The driver circuit board 1200 may further include other circuit structures, which are not listed here. The driver circuit board 1200 is electrically connected to the display panel 1100, and is used for transmitting control signals to the display panel 1100, so as to drive the display panel 1100 to realize image display. In addition, the display apparatus 1000 may further include a touch structure, an under-screen camera, and an under-screen fingerprint recognition sensor, so that the display apparatus can realize various functions such as touch, photographing, video recording, fingerprint recognition or face recognition.

Referring to FIG. 2, the display panel 1100 has a display region AA and a peripheral region BB. The peripheral region BB is located on at least one side of the display region AA. For example, the peripheral region BB is disposed around the display region AA.

The display region AA is a region of the display panel 1100 for displaying images. The display region AA is provided with a plurality of sub-pixels P therein. The sub-pixels P are the smallest light-emitting units in the display panel 1100, and are used for displaying images.

The plurality of sub-pixels P may emit light of the same color, e.g., white light or blue light. In this case, the display panel further includes a color filter layer disposed on a display side. That is, the display panel adopts a color filter (CF) on encapsulation (COE) structure. Alternatively, the plurality of sub-pixels P may emit light of different colors. For example, the plurality of sub-pixels P include red sub-pixels for emitting red light, green sub-pixels for emitting green light, and blue sub-pixels for emitting blue light.

The plurality of sub-pixels P may be arranged in a plurality of rows and a plurality of columns. Each row includes sub-pixels P arranged in a first direction X, and a plurality of rows of sub-pixels P are arranged in a second direction Y. Each column includes sub-pixels P arranged in the second direction Y, and a plurality of columns of sub-pixels P are arranged in the first direction X. The first direction X and the second direction Y intersect. For example, the first direction X is perpendicular to the second direction Y.

Each sub-pixel P includes a pixel circuit 100 and a light-emitting device 200. The pixel circuit 100 includes a plurality of thin film transistors (TFTs) and at least one capacitor Cst. For example, the pixel circuit 100 may be a “3T1C” circuit, a “7T1C” circuit, or an “8T1C” circuit. However, the embodiments of the present disclosure are not limited thereto, and any other pixel circuits may also be considered as long as the same technical concept is applied. Here, “T” represents a TFT, a number preceding “T” represents the number of TFTs, “C” represents a capacitor Cst, and a number preceding “C” represents the number of capacitors Cst.

As shown in FIG. 2, the display panel 1100 further includes a plurality of data lines DL. The plurality of data lines DL are arranged at intervals in the first direction X, and the plurality of data lines DL all extend in the second direction Y. Each data line DL may be electrically connected to a column of pixel circuits 100 in a column of sub-pixels P, and is configured to transmit a data signal to the column of pixel circuits 100 connected to the data line DL.

Referring to FIG. 2, the peripheral region BB may be used for the arrangement of a gate driver circuit (Gate on Array (GOA)) and control signal lines (such as clock signal lines, power supply voltage signal lines, etc.). Of course, the functions of the peripheral region BB are not limited to this, which will not be described in the embodiments of the present disclosure.

The peripheral region BB includes a fan-out region BB1 located on a side of the display region AA, that is, the fan-out region BB1 is a region of the peripheral region BB located on a side of the display region AA. The fan-out region BB1 is adjacent to an edge of the display region AA, that is, an edge of the fan-out region BB1 proximate to the display region AA coincides with an edge of the display region AA proximate to the fan-out region BB1. The fan-out region BB1 may be used to lead out signal lines in the peripheral region such that the signal lines are bonded to the driver circuit board or driver chip. For example, the fan-out region BB1 is adjacent to a bottom edge of the display region AA.

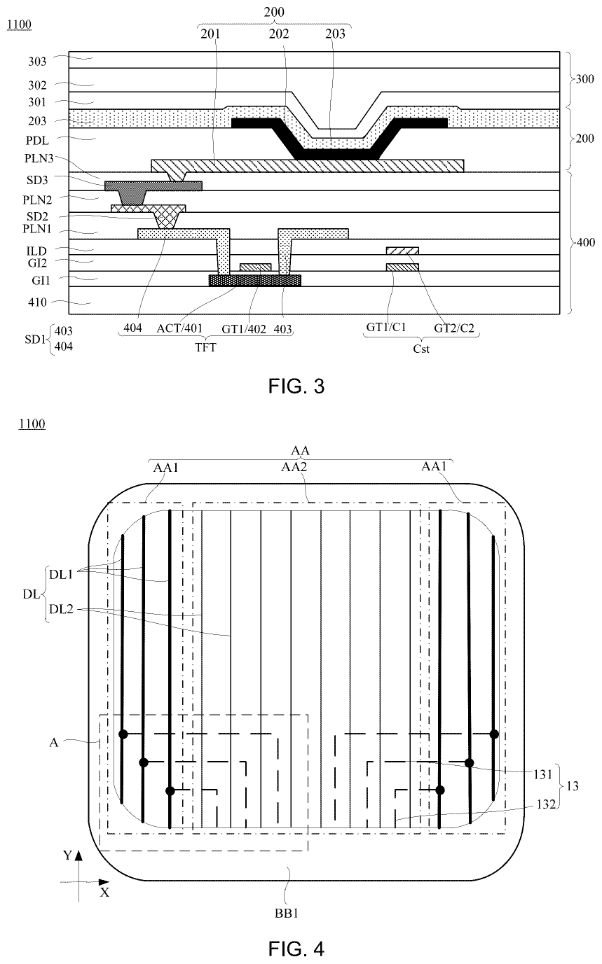

FIG. 3 is a sectional view showing a structure of a display panel according to some embodiments.

Referring to FIG. 3, in some embodiments, the display panel 1100 includes an array substrate 400, light-emitting device(s) 200 and an encapsulation layer 300 that are stacked. Of course, the display panel 1100 may further include a functional stacked layer disposed on a side of the encapsulation layer 300 away from the array substrate 400. The functional stacked layer may be, for example, one or more of a touch function layer, an anti-reflection layer, a harden layer, a color filter layer (the display panel adopts a COE structure) and an anti-fingerprint layer, so that the display panel can achieve corresponding functions. The type and quantity of the functional stacked layer will not be specifically limited in the embodiments of the present disclosure.

The array substrate 400 includes a substrate 410. The substrate 410 may be a rigid substrate, and a material of the rigid substrate includes, for example, glass. Alternatively, the substrate 410 may be a flexible substrate, and a material of the flexible substrate includes, for example, any one of polyimide (PI), polycarbonate (PC) or polyvinyl chloride (PVC).

The array substrate 400 further includes a semiconductor layer ACT, a first gate insulating layer GI1, a first gate conductive layer GT1, a second gate insulating layer GI2, a second gate conductive layer GT2, an interlayer dielectric layer ILD, a first source-drain conductive layer SD1, a first planarization layer PLN1, a second source-drain conductive layer SD2, a second planarization layer PLN2, a third source-drain conductive layer SD3, and a third planarization layer PLN3 that are sequentially arranged in a direction perpendicular to the substrate 410 and away from the substrate 410.

The thin film transistor may include, for example, a semiconductor pattern 401 located in the semiconductor layer ACT, a gate 402 located in the first gate conductive layer GT1, and a source 403 and a drain 404 that are located in the first source-drain conductive layer SD1. The capacitor Cst may include a first plate C1 located in the first gate conductive layer GT1, and a second plate C2 located in the second gate conductive layer GT2.

The light-emitting device 200 includes an anode 201, a light-emitting functional layer 202 and a cathode layer 203 that are stacked. Cathode layers 203 of a plurality of light-emitting devices 200 are connected to each other to form a continuous whole-layer structure. The display panel 1100 may further include a pixel definition layer PDL. The pixel definition layer PDL is disposed on a side of the anode 201 away from the array substrate 400. The pixel definition layer PDL includes a plurality of openings, and at least a portion of each light-emitting functional layer 202 is located in an opening.

The encapsulation layer 300 is configured to reduce the risk of water vapor and oxygen in the external environment entering the light-emitting devices 200, thereby increasing the service life of the display panel 1100. The encapsulation layer 300 may be an encapsulation film or an encapsulation substrate. For example, as shown in FIG. 3, the encapsulation layer 300 may be an encapsulation film; in this case, the encapsulation layer 300 may include a first inorganic encapsulation layer 301, an organic encapsulation layer 302 and a second inorganic encapsulation layer 303 that are sequentially stacked.

FIG. 4 is a structural diagram of a display panel 1100 according to some embodiments.

Referring to FIG. 4, the plurality of data lines DL may include a plurality of first data lines DL1 and a plurality of second data lines DL2. The plurality of first data lines DL1 are located in two edge regions AA1 of the display region AA in the first direction X, and the plurality of second data lines DL2 are located in a central region AA2 of the display region AA in the first direction X. That is, multiple first data lines DL1 are disposed on each of two sides of the plurality of second data lines DL2 in the first direction X.

Referring to FIG. 4, the display panel 1100 further includes a plurality of first connection lines 131 and a plurality of second connection lines 132.

The plurality of first connection lines 131 are arranged at intervals in the second direction Y, and the plurality of first connection lines 131 all extend in the first direction X. The plurality of first connection lines 131 are in one-to-one correspondence with the plurality of first data lines DL1. A first end (an end close to an edge region AA1 of the display region AA) of a first connection line 131 is connected to a first data line DL1, and a second end (an end close to the central region AA2 of the display region AA) of the first connection line 131 extends to the central region AA2 of the display region AA in the first direction X. For example, an end of the first connection line 131 away from the first data line DL1 extends to a region of the central region AA2 close to the edge region AA1.

The plurality of second connection lines 132 are arranged at intervals in the first direction X, and the plurality of second connection lines 132 all extend in the second direction Y. A first end (an end away from the fan-out region BB1) of a second connection line 132 is connected to a second end of a first connection line 131, and a second end (an end close to the fan-out region BB1) of the second connection line 132 extends to an edge of the display region AA close to the fan-out region BB1.

Each first data line DL1 is connected to the central region AA2 of the display region AA in the first direction X through a first connection line 131 and a second connection line 132 in sequence, and is led out from an edge of the central region AA2 close to the fan-out region BB1. This arrangement manner of the data lines DL is also called Fanout In AA (FIAA) or Fanout In Panel (FIP). It is conducive to reducing a size of the fan-out region BB1 in the second direction Y (i.e., reducing the bezel width of the display panel 1100), which is conducive to realizing the narrow bezel of the display apparatus 1000.

A first connection line 131 and a second connection line 132 that are connected to each other are referred to as a transfer line 13. A first data line DL1 is led out from the edge of the central region AA2 close to the fan-out region BB1 through a transfer line 13.

To simplify the description, in the following embodiments of the present disclosure, a region where multiple second connection lines 132 are located is referred to as a first region 101. It will be understood that the first region 101 includes a region between adjacent second connection lines 132, which forms a first region 101 with multiple second connection lines 132 that are connected to multiple first data lines DL1 on the same side. In this way, the central region AA2 of the display region AA may include two first regions 101 spaced apart in the first direction X. The first regions 101 are located within the central region AA2 of the display region AA in the first direction X.

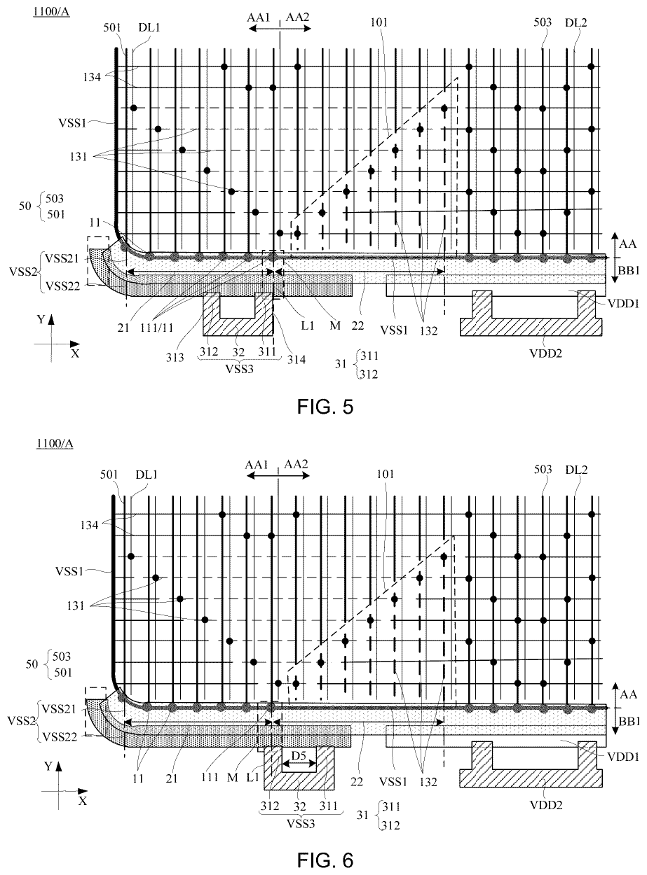

Referring to FIGS. 4 and 5, in some embodiments, in the display region AA, in addition to the regions where the second connection lines 132 are arranged, there are a plurality of power auxiliary lines 50. The plurality of power auxiliary lines 50 are arranged at intervals in the first direction X, and the plurality of power auxiliary lines 50 all extend in the second direction Y. The power auxiliary lines 50 are electrically connected to a cathode power line VSS1 in the peripheral region BB, and in turn electrically connected to the cathode layers, thereby reducing the resistances of the cathode layers, reducing the voltage drop on the cathode layers, and improving the display uniformity of the display region AA. The arrangement method of the power auxiliary lines 50 is also called VSS In Panel (SIP) technology. The cathode power line VSS1 extends along a circumferential direction of the display region AA, and at least partially surrounds the display region AA. The cathode power line VSS1 is configured to be electrically connected to the cathode layers of the display panel 1100.

It will be understood that in FIG. 5, in order to distinguish the data line DL, the first connection line 131, the second connection line 132 and the power auxiliary line 50, the data line DL, the first connection line 131, the second connection line 132 and the power auxiliary line 50 use different line types (solid line/dotted line/thin line/thick line). The thick or thin line does not represent its width, and the solid or dotted line does not represent the continuity of its extension, which are only used to distinguish different signal lines. In other drawings of the present disclosure, as specifically indicated in the drawings, each signal line is illustrated in a similar manner.

It will be understood that the plurality of data lines DL (the plurality of first data lines DL1 and the plurality of second data lines DL2), the plurality of second connection lines 132 and the plurality of power auxiliary lines 50 are arranged at intervals in the first direction X, and all extend in the second direction Y. Based on this, the plurality of data lines DL and the plurality of power auxiliary lines 50 may be arranged in the same conductive layer. For example, the plurality of data lines DL and the plurality of power auxiliary lines 50 may be arranged in the third source-drain conductive layer. The plurality of first connection lines 131 are arranged at intervals in the second direction Y, and the plurality of first connection lines 131 all extend in the first direction X. To avoid cross interference between the first connection lines 131 and the data lines DL, the first connection lines 131 may be arranged in the second source-drain conductive layer.

The plurality of power auxiliary lines 50 include a plurality of first power auxiliary lines 501. The plurality of first power auxiliary lines 501 are arranged at intervals in the first direction X, and the plurality of first power auxiliary lines 501 all extend in the second direction Y. The plurality of first power auxiliary lines 501 are located on a side of the plurality of second connection lines 132 close to the first data lines DL1. In other words, the plurality of first power auxiliary lines 501 are located on a side of the first region 101 away from the central region AA2 of the display region AA. That is, the plurality of first power auxiliary lines 501 are located in an edge region AA1 in the first direction X of the display region AA.

As shown in FIG. 5, the display panel 1100 further includes a first power bus VSS2. The first power bus VSS2 extends in the first direction X, and is connected to ends of the plurality of first power auxiliary lines 501 close to the fan-out region BB1. The first power bus VSS2 is used to electrically connect the plurality of first power auxiliary lines 501, and connect the plurality of first power auxiliary lines 501 to the fan-out region BB1, so as to facilitate transmission of a voltage signal to the plurality of first power auxiliary lines 501.

In some embodiments, as shown in FIG. 5, the first power bus VSS2 includes a first sub-line VSS21 and two second sub-lines VSS22 (only one second sub-line VSS22 is shown in FIG. 5). The first sub-line VSS21 extends along a border of the fan-out region BB1 close to the display region AA. In other words, the first sub-line VSS21 extends along a boundary line between the fan-out region BB1 and the display region AA. The first sub-line VSS21 is electrically connected to the plurality of first power auxiliary lines 501.

At least parts of the two second sub-lines VSS22 are located on a side of the first sub-line VSS21 away from the display region AA, and are electrically connected to the first sub-line VSS21. The two second sub-lines VSS22 are spaced apart in the first direction X. The two second sub-lines VSS22 are respectively located in two edge regions, in the first direction X, of the fan-out region BB1. A second sub-line VSS22 is electrically connected to a first power fan-out line VSS3.

It will be understood that, as shown in FIG. 4, the display panel 1100 may be symmetrically arranged about a center line in the first direction X. In this way, although only one second sub-line VSS22 is illustrated in FIG. 5, it may be readily known that another second sub-line VSS22 also exists in a region symmetrical to the region A in FIG. 4.

For example, the first sub-line VSS21 and the second sub-lines VSS22 may be located in different conductive layers to meet the wiring requirements of the display panel 1100. For example, the first sub-line VSS21 may be located in the third source-drain conductive layer, and the second sub-lines VSS22 may be located in the first source-drain conductive layer. Of course, the embodiments of the present disclosure are not limited thereto, as long as the same technical concept is adopted.

As shown in FIG. 5, in the first direction X, the first power bus VSS2 may include a first extension section 21 and a second extension section 22. In the second direction Y, the first extension section 21 is arranged opposite to the region where the plurality of first power auxiliary lines 501 are located, and the second extension section 22 is arranged opposite to a region where at least part of second connection lines 132 (at least part of the plurality of second connection lines 132) are located.

It will be understood that the region where the plurality of first power auxiliary lines 501 are located includes regions where the first power auxiliary lines 501 themselves are located, and a region between two adjacent first power auxiliary lines 501. In other words, the region where the plurality of first power auxiliary lines 501 are located refers to a region between a first power auxiliary line 501 closest to the first region 101 and a first power auxiliary line 501 farthest from the first region 101, and includes regions where the above-mentioned two first power auxiliary lines 501 (the first power auxiliary line 501 closest to the first region 101 and the first power auxiliary line 501 farthest from the first region 101) are located. Based on this, in the first direction X, an end of the first extension section 21 is flush with the first power auxiliary line 501 closest to the first region 101, and another end of the first extension section 21 is flush with the first power auxiliary line 501 farthest from the first region 101. Based on this, a position of the first power auxiliary line 501 closest to the first region 101 is determined as a first reference line L1, the first extension section 21 and the second extension section 22 are divided at the first reference line L1, an end of the first extension section 21 extends to the first reference line L1, and another end of the first extension section 21 extends to a first power auxiliary line 501 closest to an edge of the display region AA.

The region where at least part of the plurality of second connection lines 132 are located may be a region where second connection lines 132 close to the first power auxiliary lines 501 among the plurality of second connection lines 132 are located. The region where the second connection lines 132 are located is divided similarly to the region where the plurality of first power auxiliary lines 501 are located, which will not be described in detail in the embodiments of the present disclosure. For example, an end of the second extension section 22 in the first direction X extends to the first reference line L1 and is connected to the first extension section 21, and another end of the second extension section 22 in the first direction X extends to a border of the first region 101 away from the first data lines DL1.

It will be understood that the first power bus VSS2 is continuous in the first direction X, and two ends thereof extend beyond borders of the display region AA respectively. Based on this, the first power bus VSS2 may further include other extension sections (such as an extension section located between the two second extension sections, and a portion located on a side of the first extension section away from the second extension section), which will not be described here.

Referring to FIG. 5, the display panel 1100 further includes a first power fan-out line VSS3. The first power fan-out line VSS3 is located on a side of the first power bus VSS2 away from the display region AA, and is electrically connected to the first power bus VSS2 for connecting the first power bus VSS2 to a side of the fan-out region BB1 away from the display region AA, thus facilitating transmission of a voltage signal to the first power fan-out line VSS3.

The first power auxiliary line 501 is electrically connected to the first power fan-out line VSS3 through the first sub-line VSS21 and the second sub-line VSS22 in sequence. For example, the first power fan-out line VSS3 and the second sub-line VSS22 are located in different conductive layers to meet the wiring requirements of the display panel 1100. For example, the first power fan-out line VSS3 may be located in the second source-drain conductive layer.

In some embodiments, the first power fan-out line VSS3 is further configured to be connected to a power management chip DC/DC of a driver circuit board (not shown in FIG. 5). For example, the first power fan-out line VSS3 is connected to the power management chip of the driver circuit board through a flexible printed circuit (FPC). In this way, the power management chip may be electrically connected to the power auxiliary lines 50 and the cathode layers through the FPC, the first power fan-out line VSS3, the first power bus VSS2, and the cathode power line VSS1 in sequence, and transmits a power signal to the cathode layers.

It has been found through research that, in the case where the first power fan-out line VSS3 is arranged on a side of the first region 101 close to the fan-out region BB1 (that is, in the first direction X, the first power fan-out line VSS3 is closer to the central region AA2 of the display region AA than the first power auxiliary lines 501), currents on the first power auxiliary lines 501 and currents on portions of the cathode power line VSS1 located on two sides of the display region AA in the first direction X are transmitted to the first power bus VSS2 along the second direction Y, and then transmitted to the first power fan-out line VSS3 along the first direction X on the first power bus VSS2. In this way, at junctions between (one or more) first power auxiliary lines 501 close to the first region 101 and the first power bus VSS2, there are the current transmitted along the first power bus VSS2 and along the first direction X and the currents transmitted along the first power auxiliary lines 501 and along the second direction Y, resulting in a large current density. That is, in a region where the first power auxiliary line(s) 501 close to the first region 101 are connected to the first power bus VSS2, the current density is large, which leads to heat accumulation and easily causes burning at this location, increasing the risk of failure of the material of the light-emitting functional layer of the light-emitting device in this region.

In order to solve the above technical problems and reduce the current density in the region where the first power auxiliary line(s) 501 close to the first region 101 are connected to the first power bus VSS2, the embodiments of the present disclosure provide a display panel 1100. As shown in FIG. 5, the first power fan-out line VSS3 includes a contact portion 31, the contact portion 31 is in contact with and connected to the first power bus VSS2, and the contact portion 31 includes a first sidewall 313, the first sidewall 313 is close to an edge region AA1 of the display region AA in the first direction X. That is, the first sidewall 313 is a sidewall of the contact portion 31 close to an edge of the display region AA. The first power auxiliary line 501 includes at least one current confluence point 11 connected to the first power bus VSS2. In the first direction X, the at least one current confluence point 11 is closer to the central region AA2 of the display region AA in the first direction X than the first sidewall 313.

The contact portion 31 refers to a portion of the first power fan-out line VSS3 connected to the first power bus VSS2. A sidewall of the contact portion 31 close to an edge region AA1 of the display region AA in the first direction X is the first sidewall 313. A position where the first power auxiliary line 501 is electrically connected to the first power bus VSS2 forms a current confluence point 11. A current on the first power auxiliary line 501 may be transmitted from the current confluence point 11 to the first power bus VSS2.

The at least one current confluence point 11 is closer to the central region AA2 of the display region AA in the first direction X than the first sidewall 313. In the embodiments of the present disclosure, a current confluence point 11 located on a side of the first sidewall 313 close to the central region AA2 of the display region AA in the first direction X is a first current confluence point 111. That is, at least part of the contact portion 31 is electrically connected to a side of the first current confluence point 111 away from the central region AA2 of the display region AA in the first direction X.

The first current confluence point 111 is closer to the central region AA2 of the display region AA in the first direction X than the first sidewall 313, which may be that the first current confluence point 111 and the contact portion 31 are arranged opposite to each other in the second direction Y, or the first current confluence point 111 is located on a side of the contact portion 31 close to the central region AA2 of the display region AA in the first direction X.

For example, when the first current confluence point 111 and the contact portion 31 are arranged opposite to each other in the second direction Y, the current of the first power auxiliary line 501 transmitted from the first current confluence point 111 to the first power bus VSS2 may be directly transmitted on the first power bus VSS2 to the contact portion 31 in the second direction Y and in a direction toward the fan-out region BB1 (in a direction from top to bottom), and then transmitted to the first power fan-out line VSS3.

For example, when the first current confluence point 111 is located on the side of the contact portion 31 close to the central region AA2 of the display region AA in the first direction X, the current transmitted from the first current confluence point 111 by the first power auxiliary line 501 to the first power bus VSS2 may be transmitted on the first power bus VSS2 in the first direction X and in a direction away from the central region AA2 of the display region AA in the first direction X (in the first direction X and in a direction away from the central region AA2) to the contact portion 31, and then transmitted to the first power fan-out line VSS3.

Based on this, when the at least one current confluence point 11 is closer to the central region AA2 of the display region AA in the first direction X than the first sidewall 313, at least part of currents on multiple first power auxiliary lines 501 may be directly transmitted from the first current confluence point 111 to the contact portion 31 outward (in the first direction X and in the direction away from the central region AA2) or downward (in the second direction Y and in a direction pointing from the display region AA to the fan-out region BB1), thus reducing the current at a location (hereinafter referred to as a target region M) where the first power auxiliary line(s) 501 close to the first region 101 are connected to the first power bus VSS2, and in turn reducing the current density of the target region M, ameliorating the problem of heat accumulation in the target region M, and reducing the risk of failure of the material of the light-emitting functional layer of the light-emitting device in the target region M.

As shown in FIG. 5, in some embodiments, the first power auxiliary line 501 includes a current confluence point 11 connected to the first power bus VSS2, and an end of the first power auxiliary line 501 close to the fan-out region BB1 is electrically connected to the first power bus VSS2 to form the current confluence point 11.

In some embodiments, as shown in FIG. 5, at least part of the contact portion 31 is in contact with and connected to the first extension section 21. In this way, at least part of currents of the first power auxiliary lines 501 may be transmitted to the contact portion 31 from a portion where the contact portion 31 is in contact with and connected to the first extension section 21, and further transmitted to the first power fan-out line VSS3, thereby reducing the current density of the target region M, ameliorating the problem of heat accumulation in the target region M, and reducing the risk of failure of the material of the light-emitting functional layer of the light-emitting device in the target region.

It will be understood that in the embodiments of the present disclosure, “in contact with and connected to” means that two objects are in direct contact with and connected to each other, where the two may be located in the same conductive layer or different conductive layers. When the two are located in different conductive layers, the two may be connected through a via hole. For example, the contact portion 31 is in contact with and connected to the first extension section 21, the contact portion 31 is located in the second source-drain conductive layer, the first extension section 21 is located in the first source-drain conductive layer, and the contact portion 31 is connected to the first extension section 21 through a via hole.

For example, the contact portion 31 may be partially in contact with and connected to the first extension section 21, and partially in contact with and connected to the second extension section 22 (as shown in FIGS. 6 to 9). Alternatively, the contact portion 31 may be completely in contact with and connected to the first extension section 21 (as shown in FIGS. 5 and 10).

In some embodiments, referring to FIG. 6, the contact portion 31 includes a first sub-portion 311 and a second sub-portion 312. The first sub-portion 311 is in contact with and connected to the second extension section 22, and has a distance D5 from the first extension section 21. The second sub-portion 312 and the first sub-portion 311 are spaced apart in the first direction X, and the second sub-portion 312 is located on a side of the first sub-portion 311 away from the central region AA2 of the display region AA in the first direction X (the left side in FIG. 6). A part of the second sub-portion 312 is in contact with and connected to the first extension section 21, and another part of the second sub-portion 312 is in contact with and connected to the second extension section 22. That is to say, only a part of the contact portion 31 that is away from the central region AA2 of the display region AA is in contact with and connected to the first extension section 21. In this way, it is conducive to increasing a spacing between the first power fan-out line VSS3 and an edge of the display panel 1100 in the first direction X (i.e., increasing the space on the left of the first power fan-out line VSS3), and improving the wiring space of the fan-out region BB1, which facilitates the wiring design of signal lines of the gate driver circuit.

It will be understood that, FIG. 6 is a structural diagram of the display panel where a part of the second sub-portion is in contact with and connected to the first extension section and the entire first sub-portion is in contact with and connected to the second extension section. In addition, the contact portion 31 is set as the first sub-portion 311 and the second sub-portion 312 that are spaced apart, which facilitates the arrangement of other wiring between the first sub-portion 311 and the second sub-portion 312 (for example, signal lines of the touch structure may be arranged between the first sub-portion 311 and the second sub-portion 312).

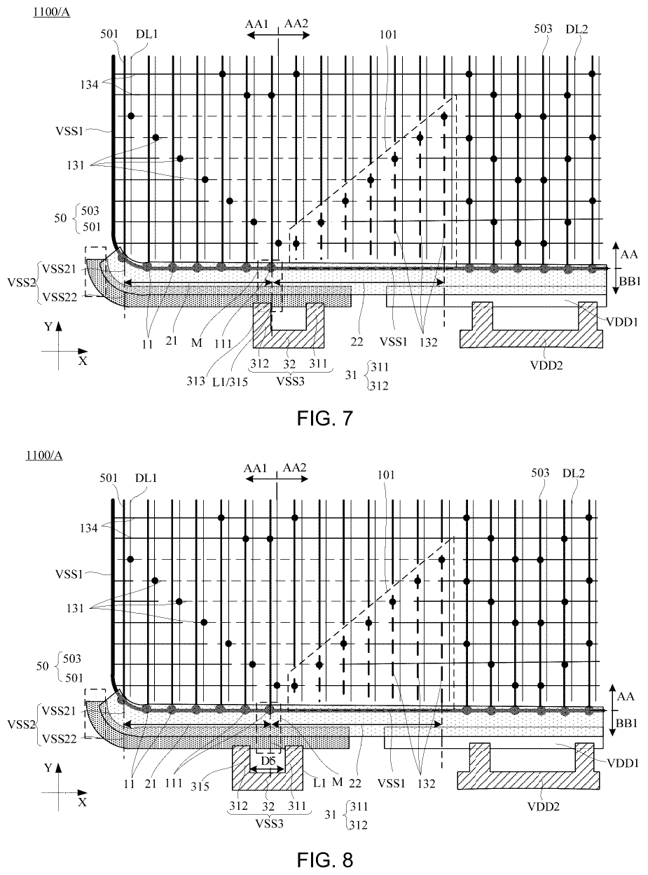

In some other embodiments, referring to FIG. 7, the contact portion 31 includes a first sub-portion 311 and a second sub-portion 312. The first sub-portion 311 is in contact with and connected to the second extension section 22, and has a distance from the first extension section 21. The second sub-portion 312 and the first sub-portion 311 are spaced apart in the first direction X, and the second sub-portion 312 is located on a side of the first sub-portion 311 away from the central region AA2 of the display region AA in the first direction X (the left side in FIG. 7). FIG. 7 is a structural diagram of the display panel where the second sub-portion is in contact with and connected to the first extension section and the first sub-portion is in contact with and connected to the second extension section.

The second sub-portion 312 (the entirety of the second sub-portion 312 in the first direction X) is in contact with and connected to the first extension section 21. In this way, the entire second sub-portion 312 is in contact with the first extension section 21, which may increase the length that the contact portion 31 is in contact with the first extension section 21, thereby increasing the current directly transmitted to the second sub-portion 312 and reducing the current density of the target region M. In addition, the spacing between the first power fan-out line VSS3 and the edge of the display panel 1100 in the first direction X may be taken into account at the same time, which is conducive to increasing the wiring space in the fan-out region BB1 on a side of the first power fan-out line VSS3 away from the central region AA2 of the display region AA, which facilitates the wiring design of the signal lines of the gate driver circuit.

For example, in some display panels with small wiring space, the structure design of the first power fan-out line VSS3 as shown in FIG. 6 or 7 may be adopted, which may reduce the current density of the target region M and ensure the wiring space on the side of the first power fan-out line VSS3 away from the central region AA2 of the display region AA.

In some embodiments, as shown in FIG. 7, a sidewall 315 (hereinafter referred to as a third sidewall 315) of the second sub-portion 312 close to the first sub-portion 311 is flush with the first reference line L1. In this way, the current directly transmitted to the second sub-portion 312 by the first extension section 21 is increased, and the current density in the target region M is reduced; furthermore, the wiring space on the side of the first power fan-out line VSS3 away from the central region AA2 of the display region AA may be greatly increased.

The first reference line L1 coincides with a first power auxiliary line 501 that is closest to the central region AA2 of the display region AA in the first direction X. In other words, a position of the first power auxiliary line 501 that is closest to the central region AA2 of the display region AA in the first direction X among the plurality of first power auxiliary lines 501 is the first reference line L1.

Of course, in some other embodiments, referring to FIG. 8, the sidewall (third sidewall 315) of the second sub-portion 312 close to the first sub-portion 311 may be located on a side of the first reference line L1 away from the second sub-portion 312. In this way, the current transmitted to the first power bus VSS2 by some first power auxiliary lines 501 close to the first region 101 may be transmitted to the first sub-portion 311 in a direction away from the first region 101, thereby reducing the current density in the target region M. FIG. 8 is a structural diagram of the display panel where the second sub-portion and the first reference line are spaced apart.

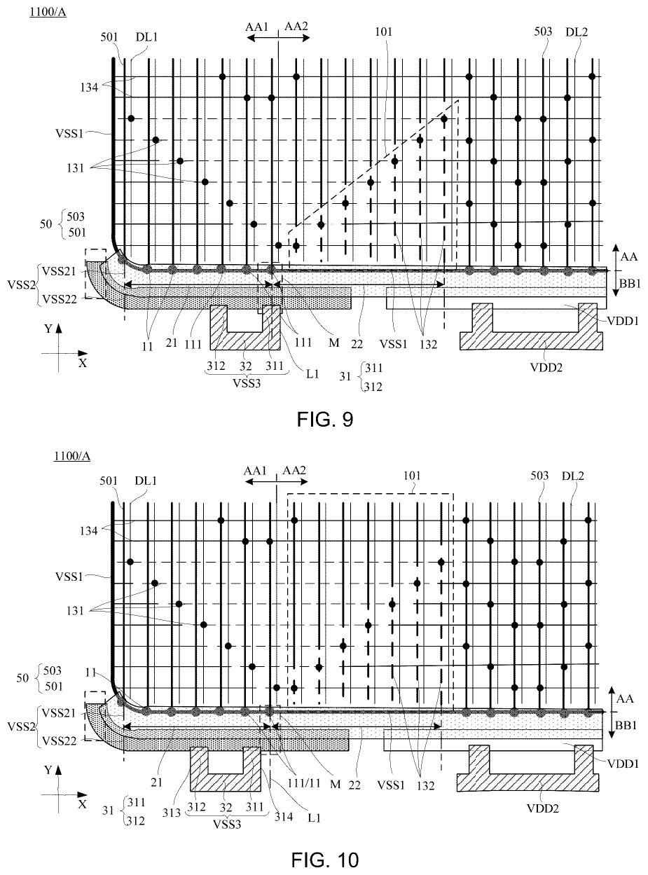

In some embodiments, referring to FIG. 9, the contact portion 31 includes a first sub-portion 311 and a second sub-portion 312. The second sub-portion 312 and the first sub-portion 311 are spaced apart in the first direction X, and the second sub-portion 312 is located on the side of the first sub-portion 311 away from the central region AA2 of the display region AA in the first direction X. For example, the second sub-portion 312 and the first sub-portion 311 have a spacing therebetween. A part of the first sub-portion 311 is in contact with and connected to the first extension section 21, and another part of the first sub-portion 311 is in contact with and connected to the second extension section 22. The second sub-portion 312 is in contact with and connected to the first extension section 21. In this way, the length that the first power fan-out line VSS3 is connected to the first extension section 21 of the first power bus VSS2 may be further increased, so that the currents on the plurality of first power auxiliary lines 501 and the cathode power line VSS1 may be more directly transmitted to the first power fan-out line VSS3 from portions that the second sub-portion 312 and the first sub-portion 311 are in contact with the first extension section 21, thereby reducing the current of the target region M, reducing the current density in the target region M, and reducing the risk of heat accumulation in the target region M and damage to the light-emitting devices. FIG. 9 is a structural diagram of the display panel where the second sub-portion is in contact with connected to the first extension section and a part of the first sub-portion is in contact with and connected to the second extension section.

In some other embodiments, referring to FIG. 10, the contact portion 31 includes a first sub-portion 311 and a second sub-portion 312. The second sub-portion 312 and the first sub-portion 311 are spaced apart in the first direction X, and the second sub-portion 312 is located on the side of the first sub-portion 311 away from the central region of the display region AA in the first direction X. For example, the second sub-portion 312 and the first sub-portion 311 have a spacing therebetween. The first sub-portion 311 and the second sub-portion 312 are both in contact with and connected to the first extension section 21. In this way, the length that the first power fan-out line VSS3 is connected to the first extension section 21 of the first power bus VSS2 may be greatly increased, and the currents transmitted from the first power auxiliary lines 501 and the cathode power lines VSS1 to the target region M may be greatly reduced, thereby greatly reducing the current density of the target region M and reducing the risk of heat accumulation in the target region M and damage to the light-emitting devices. FIG. 10 is a structural diagram of the display panel where the entire contact portion is in contact with and connected to the first extension section and the contact portion and the first reference line are spaced apart.

For example, referring to FIG. 10, a sidewall (second sidewall 314) of the first sub-portion 311 close to the central region AA2 of the display region AA in the first direction X is located on a side of the first reference line L1 away from the central region AA2 of the display region AA in the first direction X. In this way, the current transmitted to the first power bus VSS2 by some first power auxiliary lines 501 close to the first region 101 may be transmitted to the first sub-portion 311 in the direction away from the first region 101, thereby reducing the current density in the target region M.

The first reference line L1 coincides with a first power auxiliary line 501 that is closest to the central region AA2 of the display region AA in the first direction X. In other words, a position of the first power auxiliary line 501 that is closest to the central region AA2 of the display region AA in the first direction X among the plurality of first power auxiliary lines 501 is the first reference line L1.

For example, referring to FIG. 5, the sidewall (hereinafter referred to as the second sidewall 314) of the first sub-portion 311 close to the central region AA2 of the display region AA in the first direction X is flush with the first reference line L1. In this way, the current directly transmitted to the second sub-portion 312 by the first extension section 21 is increased, and the current density in the target region M is reduced; furthermore, the wiring space on the side of the first power fan-out line VSS3 away from the central region AA2 of the display region AA may be greatly increased.

For example, referring to FIGS. 5, 9 and 10, in some display panels with sufficient wiring space in the fan-out region BB1, for example, in the case where the wiring space on the side of the first power fan-out line VSS3 away from the central region AA2 of the display region AA is large, the structure design of the first power fan-out line VSS3 as shown in FIGS. 5, 9 and 10 may be adopted. In this way, the current density of the target region M may be greatly reduced, thereby reducing the current density in the target region M and reducing the risk of heat accumulation in the target region M and damage to the light-emitting devices.

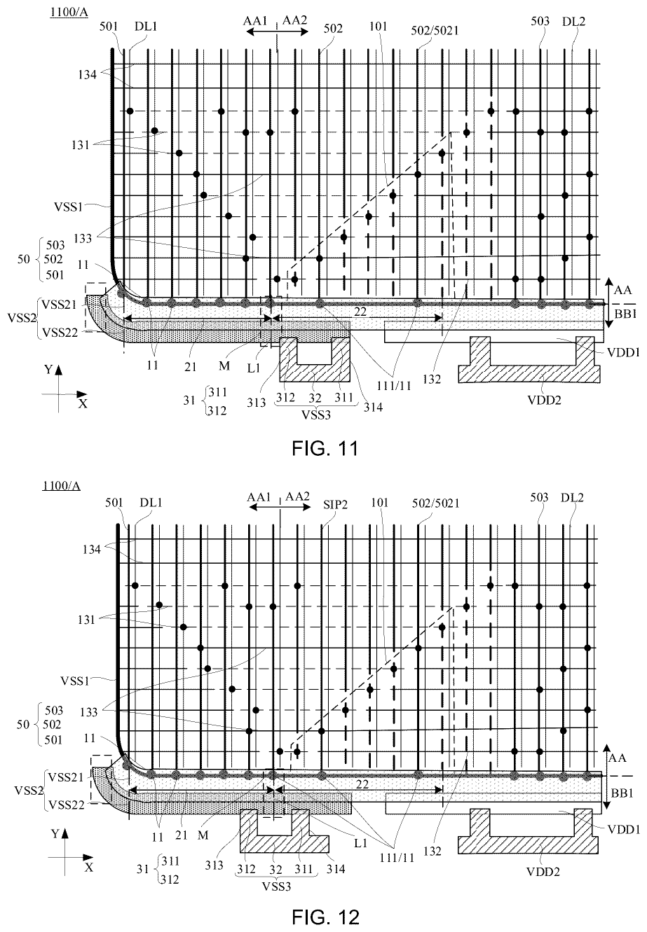

Referring to FIG. 11, in some embodiments, at least one first power auxiliary line 501 includes two current confluence points 11 connected to the first power bus VSS2. In this case, the display panel 1100 further includes at least one second power auxiliary line 502 and at least one third connection line 133. FIG. 11 is a structural diagram of the display panel including the second power auxiliary line.

The second power auxiliary line 502 extends in the second direction Y. Each second power auxiliary line 502 is located between two adjacent second connection lines 132. An end of the second power auxiliary line 502 close to the fan-out region BB1 is connected to the first power bus VSS2. That is, the plurality of power auxiliary lines 50 further include the at least one second power auxiliary line 502, and the second power auxiliary line(s) 502 are located in the first region 101.

An end of each first power auxiliary line 501 close to the fan-out region BB1 is connected to the first power bus VSS2 to form a current confluence point 11. At least one first power auxiliary line 501 is connected to the first power bus VSS2 through a third connection line 133 and a second power auxiliary line 502 in sequence, so as to form a current confluence point 11. In this way, the current on the at least one first power auxiliary line 501 may be transmitted to the first power bus VSS2 through the third connection line 133 and the second power auxiliary line 502 in sequence, thereby reducing the current flowing through the target region M and reducing the current density of the target region M.

In some embodiments, as shown in FIG. 11, the display panel 1100 further includes a plurality of auxiliary connection lines 134. The plurality of auxiliary connection lines 134 are arranged at intervals in the second direction Y, and the plurality of auxiliary connection lines 134 all extend in the first direction X. The third connection line 133 may be used as an auxiliary connection line 134.

It will be understood that each auxiliary connection line 134 of the plurality of auxiliary connection lines 134 is electrically connected to at least one power auxiliary line 50, so that the plurality of power auxiliary lines 50 are connected to form a mesh structure. Thus, the resistance of the plurality of power auxiliary lines 50 and the plurality of auxiliary connection lines 134 is reduced, and the voltage drop of the plurality of power auxiliary lines 50 and the plurality of auxiliary connection lines 134 is reduced.

The plurality of auxiliary connection lines 134 and the plurality of first power auxiliary lines 501 are located in different conductive layers, so as to reduce the risk of signal interference between the plurality of auxiliary connection lines 134 and the plurality of first power auxiliary lines 501. For example, the plurality of auxiliary connection lines 134 may be arranged in the second source-drain conductive layer, and the plurality of first power auxiliary lines 501 may be arranged in the third source-drain conductive layer.

Referring to FIG. 11, in some embodiments, the first power bus VSS2 includes a first extension section 21 and a second extension section 22. In the second direction Y, the first extension section 21 is arranged opposite to the region where the plurality of first power auxiliary lines 501 are located, and the second extension section 22 is arranged opposite to a region where (all) second power auxiliary lines 502 and at least some of the plurality of second connection lines 132 are located.

At least part of the contact portion 31 is connected to the second extension section 22, which is conducive to increasing the wiring space on the side of the first power fan-out line VSS3 away from the central region AA2 of the display region AA and reducing the size of the fan-out region BB1 in the first direction X. For example, as shown in FIG. 11, the contact portion 31 may be entirely connected to the second extension section 22, and there is a spacing between the contact portion 31 (the second sub-portion 312) and the first reference line L1.

It will be understood that the region where the plurality of first power auxiliary lines 501 are located includes regions where the first power auxiliary lines 501 themselves are located, and a region between two adjacent first power auxiliary lines 501. In other words, the region where the plurality of first power auxiliary lines 501 are located refers to a region between a first power auxiliary line 501 closest to the first region 101 and a first power auxiliary line 501 farthest from the first region 101, and includes regions where the above-mentioned two first power auxiliary lines 501 are located. Based on this, in the first direction X, an end of the first extension section 21 is flush with the first power auxiliary line 501 closest to the first region 101, and another end of the first extension section 21 is flush with the first power auxiliary line 501 farthest from the first region 101.

The region where the second power auxiliary lines 502 and at least some of the plurality of second connection lines 132 are located includes: a region where the second power auxiliary lines 502 and some of the second connection lines 132 themselves are located, a region located between adjacent second connection lines 132, a region located between adjacent second power auxiliary lines 502, and a region located between adjacent second power auxiliary line 502 and second connection line 132.

Referring to FIG. 11, in some embodiments, the entire contact portion 31 is in contact with and connected to the second extension section 22. In the first direction X, the first sidewall 313 of the contact portion 31 is closer to the central region AA2 of the display region AA in the first direction X than the plurality of first power auxiliary lines 501. That is, a left border of the contact portion 31 is located on the left side of the first reference line L1. In this way, the wiring space on the side of the first power fan-out line VSS3 away from the central region AA2 of the display region AA may be greatly increased.

The contact portion 31 further includes a second sidewall 314, and the second sidewall 314 is close to the central region AA2 of the display region AA in the first direction X. That is, the second sidewall 314 is a sidewall of the contact portion 31 close to the center of the display region AA. As shown in FIG. 11, the second sidewall 314 is closer to the first sidewall 313 than a second power auxiliary line 502 (hereinafter referred to as a target second power auxiliary line 5021) that is closest to the central region AA2 of the display region AA in the first direction X. That is to say, in the first direction X, there is a spacing between the second sidewall 314 and the target second power auxiliary line 5021. Alternatively, the second sidewall 314 is flush with the second power auxiliary line 502 that is closest to the central region AA2 of the display region AA in the first direction X (not shown in the figure).

For example, as shown in FIG. 11, the second sidewall 314 is flush with an edge of the second sub-line VSS22 close to the central region AA2 of the display region AA.

In some other embodiments, referring to FIG. 12, the contact portion 31 includes a first sub-portion 311 and a second sub-portion 312. The second sub-portion 312 and the first sub-portion 311 are spaced apart in the first direction X, and the second sub-portion 312 is located on a side of the first sub-portion 311 away from the central region AA2 of the display region AA in the first direction X (the left side in FIG. 12). At least part of the first sub-portion 311 is in contact with and connected to the second extension section 22, and at least part of the second sub-portion 312 is in contact with and connected to the first extension section 21. Based on this, it may be possible to reduce the current flowing through the target region M, reduce the current density of the target region M, and reduce the risk of heat accumulation in the target region M and damage to the light-emitting devices.

For example, as shown in FIG. 12, the entire first sub-portion 311 is in contact with and connected to the second extension section 22, and the entire second sub-portion 312 is in contact with and connected to the first extension section 21. Of course, in some other examples, a part of the first sub-portion 311 is in contact with the second extension section 22, and another part of the first sub-portion 311 is in contact with the first extension section 21; and the entire second sub-portion 312 is in contact with the first extension section 21 (not shown in the figure). Alternatively, the entire first sub-portion 311 is in contact with and connected to the second extension section 22, a part of the second sub-portion 312 is in contact with and connected to the first extension section 21, and another part of the second sub-portion 312 is in contact with and connected to the second extension section 22 (not shown in the figure).

In some embodiments, as shown in FIG. 12, the display panel 1100 includes a plurality of second power auxiliary lines 502. The number of second connection lines 132 arranged between two adjacent second power auxiliary lines 502 is in a range of 2 to 7, inclusive, which may be flexibly set based on the number of the second power auxiliary lines 502 and the number of the first data lines DL1. For example, there may be two, three, four, five, six or seven second connection lines 132 arranged between two adjacent second power auxiliary lines 502. For example, as shown in FIG. 12, three second connection lines 132 may be arranged between two adjacent second power auxiliary lines 502. FIG. 12 is a structural diagram of the display panel where the second power auxiliary lines are included and at least part of the contact portion is in contact with the first extension section.

In some embodiments, as shown in FIGS. 11 and 12, the first sub-portion 311 and the second sub-portion 312 both extend in the second direction Y, and a first end (an end close to the display region AA) of the first sub-portion 311 and a first end (an end close to the display region AA) of the second sub-portion 312 are both connected to the first power bus VSS2 (the second sub-line VSS22). The first power fan-out line VSS3 further includes a bonding portion 32, and the bonding portion 32 extends in the first direction X. Two ends of the bonding portion 32 in the first direction X are respectively connected to a second end (an end away from the display region AA) of the first sub-portion 311 and a second end (an end away from the display region AA) of the second sub-portion 312, so that the first sub-portion 311 and the second sub-portion 312 are connected as a whole. For example, the bonding portion 32 is configured to be bonded and connected to the FPC, and to be electrically connected to the driver circuit board through the FPC.

For example, as shown in FIG. 11, the two ends of the bonding portion 32 in the first direction X may be flush with the first sidewall 313 of the first sub-portion 311 and the second sidewall 314 of the second sub-portion 312, respectively. Alternatively, as shown in FIG. 12, an end of the bonding portion 32 in the first direction X is flush with the first sidewall 313 of the first sub-portion 311, and another end of the bonding portion 32 in the first direction X extends beyond the second sidewall 314 of the second sub-portion 312. Alternatively, an end of the bonding portion 32 in the first direction X extends beyond the first sidewall 313 of the first sub-portion 311, and another end of the bonding portion 32 in the first direction X is flush with the second sidewall 314 of the second sub-portion 312 (not shown in the figure).

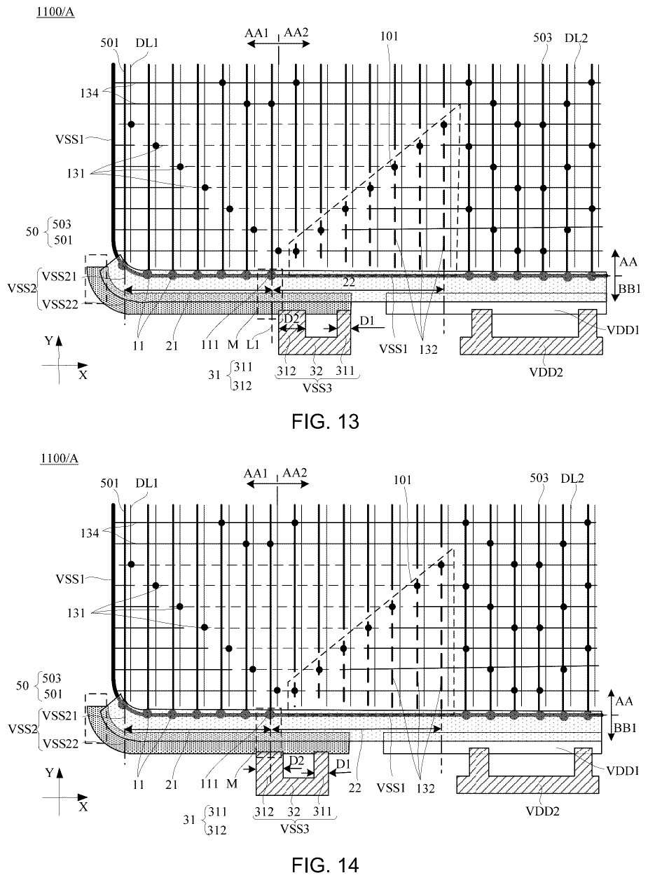

Referring to FIG. 13, in some embodiments, a size D2 of the second sub-portion 312 in the first direction X is greater than a size D1 of the first sub-portion 311 in the first direction X. The cathode layers of the display panel 1100 are directly electrically connected to the cathode power line VSS1, and the currents transmitted by the cathode layers are mainly concentrated in the cathode power line VSS1. In other words, the current on the cathode power line VSS1 is greater than the current on the power auxiliary line 50. The current on the cathode power line VSS1 converges from a side far away from the fan-out region BB1 to a side close to the fan-out region BB1. Based on this, since the second sub-portion 312 is closer to a portion of the cathode power line VSS1 on one of the two sides of the display region AA in the first direction X than the first sub-portion 311, the current on the second sub-portion 312 is greater than the current on the first sub-portion 311. The size D2 of the second sub-portion 312 in the first direction X is greater than the size D1 of the first sub-portion 311 in the first direction X, so that an area of the second sub-portion 312 may be increased. Therefore, it is possible to reduce the current density on the second sub-portion 312, balance the current density on the second sub-portion 312 and the first sub-portion 311, and reduce the risk of heat accumulation and temperature rise of the second sub-portion 312. FIG. 13 is a structural diagram of the display panel where a width of the second sub-portion is greater than a width of the first sub-portion.

It will be understood that, in the embodiments of the present disclosure, as shown in FIG. 13, the size D2 of the second sub-portion 312 in the first direction X is greater than the size D1 of the first sub-portion 311 in the first direction X, which may be implemented independently of other embodiments or in combination with any one or more embodiments mentioned above. That is, in the case where the size D2 of the second sub-portion 312 in the first direction X is greater than the size D1 of the first sub-portion 311 in the first direction X, the positions where the first sub-portion 311 and the second sub-portion 312 are connected to the first power bus VSS2 may be arbitrarily determined according to needs.

For example, as shown in FIG. 13, the first sub-portion 311 and the second sub-portion 312 may both be in contact with and connected to the second extension section 22 of the first power bus VSS2.

As shown in FIG. 14, in some embodiments, the size D2 of the second sub-portion 312 in the first direction X is greater than the size D1 of the first sub-portion 311 in the first direction X, so as to reduce the current density on the second sub-portion 312 and balance the current density on the second sub-portion 312 and the first sub-portion 311. Moreover, a part of the second sub-portion 312 is in contact with and connected to the first extension section 21, another part of the second sub-portion 312 is in contact with and connected to the second extension section 22, and the entire first sub-portion 311 is in contact with and connected to the second extension section 22, so as to reduce the current density in the target region M, and reduce the risk of heat accumulation in the target region M and damage to the light-emitting devices. FIG. 14 is a structural diagram of the display panel where a part of the second sub-portion is in contact with and connected to the first extension section.

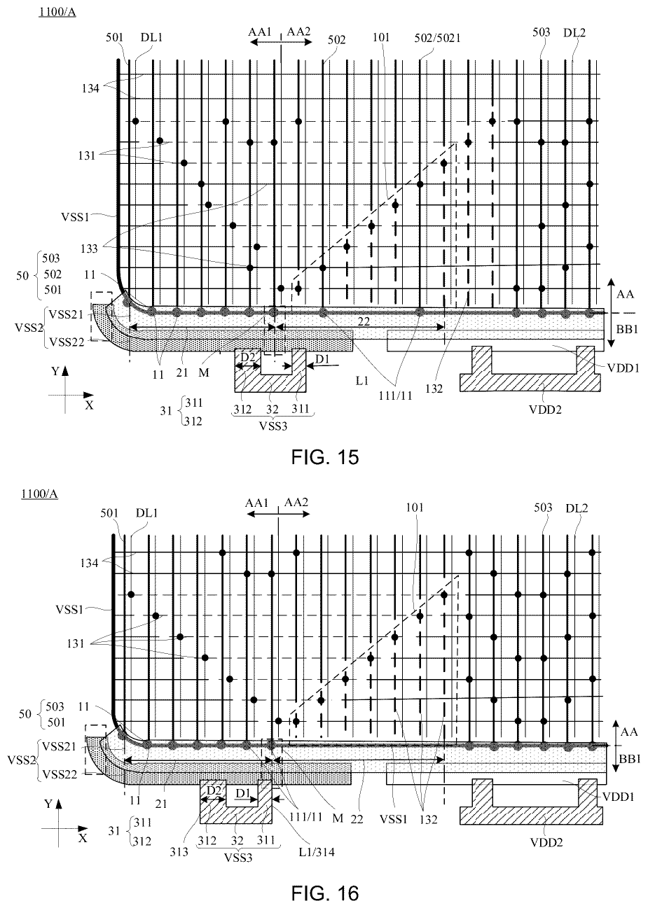

As shown in FIG. 15, in some other embodiments, the size D2 of the second sub-portion 312 in the first direction X is greater than the size D1 of the first sub-portion 311 in the first direction X, so as to reduce the current density on the second sub-portion 312 and balance the current density on the second sub-portion 312 and the first sub-portion 311. The entire second sub-portion 312 is in contact with the first extension section 21, and the first sub-portion 311 is in contact with the second extension section 22. Based on this, it may be possible to further reduce the current density in the target region M, and reduce the risk of heat accumulation in the target region M and damage to the light-emitting devices. FIG. 15 is a structural diagram of the display panel where the second sub-portion is in contact with and connected to the first extension section, and the first sub-portion is in contact with and connected to the second extension section.

As shown in FIG. 16, in yet some other embodiments, the size D2 of the second sub-portion 312 in the first direction X is greater than the size D1 of the first sub-portion 311 in the first direction X, so as to reduce the current density on the second sub-portion 312 and balance the current density on the second sub-portion 312 and the first sub-portion 311. The entire first sub-portion 311 and the entire second sub-portion 312 are in contact with and connected to the first extension section 21, which may greatly reduce the current density in the target region M, and reduce the risk of heat accumulation in the target region M and damage to the light-emitting devices. FIG. 16 is a structural diagram of the display panel where both the first sub-portion and the second sub-portion are in contact with and connected to the first extension section.

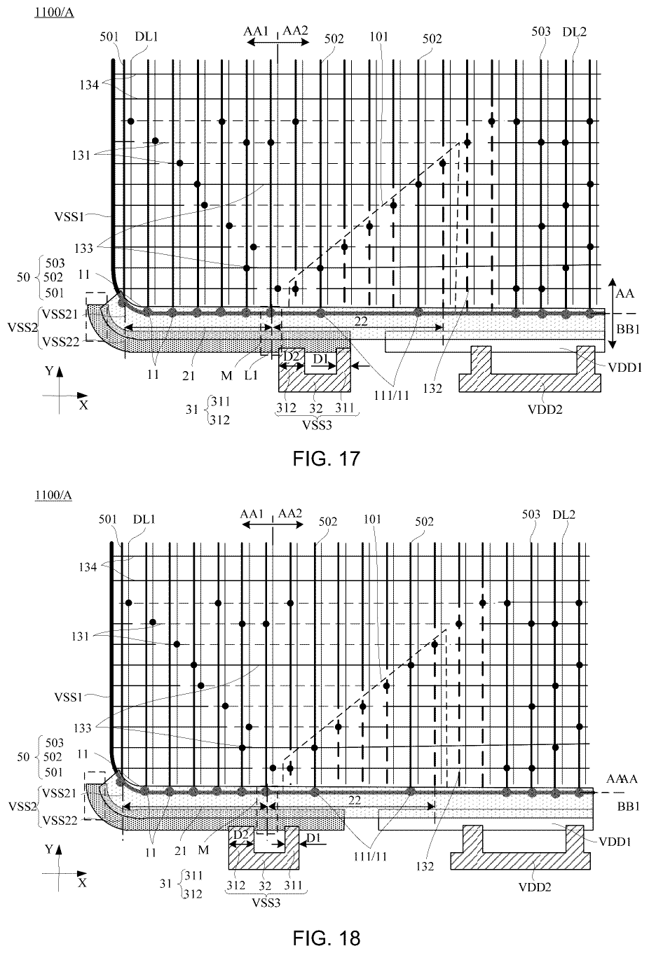

As shown in FIG. 17, in yet some other embodiments, the size D2 of the second sub-portion 312 in the first direction X is greater than the size D1 of the first sub-portion 311 in the first direction X, so as to reduce the current density on the second sub-portion 312 and balance the current density on the second sub-portion 312 and the first sub-portion 311. The plurality of power auxiliary lines 50 include second power auxiliary line(s) 502, and the entire first sub-portion 311 and the entire second sub-portion 312 may all be in contact with and connected to the second extension section 21. Based on this, the wiring space of the fan-out region BB1 may be increased, which facilitates the wiring design of the signal lines of the gate driver circuit; in addition, it may be possible to reduce the current density in the target region M, and reduce the risk of heat accumulation in the target region M and damage to the light-emitting devices. FIG. 17 is a structural diagram of the display panel where the width of the second sub-portion is greater than the width of the first sub-portion, and both the first sub-portion and the second sub-portion are in contact with and connected to the second extension section.

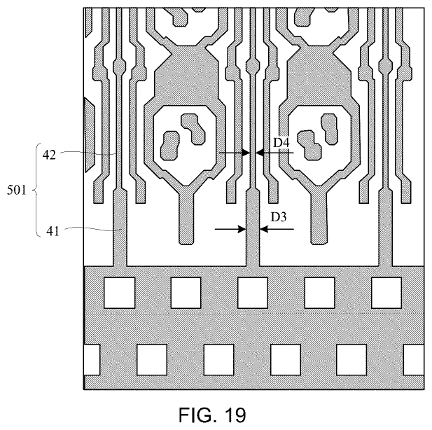

As shown in FIG. 18, in yet some other embodiments, the size D2 of the second sub-portion 312 in the first direction X is greater than the size D1 of the first sub-portion 311 in the first direction X, so as to reduce the current density on the second sub-portion 312 and balance the current density on the second sub-portion 312 and the first sub-portion 311. The plurality of power auxiliary lines 50 include second power auxiliary line(s) 502, at least part of the first sub-portion 311 is in contact with and connected to the second extension section 22, and at least part of the second sub-portion 312 is in contact with and connected to the first extension section 21. Based on this, the wiring space of the fan-out region BB1 may be increased, which facilitates the wiring design of the signal lines of the gate driver circuit; and it may be possible to further reduce the current density in the target region M, and reduce the risk of heat accumulation in the target region M and damage to the light-emitting devices. FIG. 18 is a structural diagram of the display panel where the width of the second sub-portion is greater than the width of the first sub-portion, the second sub-portion is in contact with the first extension section, and the first sub-portion is in contact with the second extension section.

In some embodiments, the size of the first sub-portion 311 in the first direction is D1, the size of the second sub-portion 312 in the first direction is D2, and D1 and D2 satisfy: D2=(1.2˜4)×D1. That is, in the first direction X, the size of the second sub-portion 312 is 1.2 to 4 times the size of the first sub-portion 311. For example, D2=1.2D1, D2=2D1, D2=3.5D1, or D2=4D1, which are not all listed in the embodiments of the present disclosure.

In some embodiments, referring to FIG. 19, the first power auxiliary line 501 includes a third extension section 41 and a fourth extension section 42. The third extension section 41 is connected to the first power bus VSS2. The fourth extension section 42 is located on a side of the third extension section 41 away from the fan-out region BB1, and is connected to the third extension section 41. A size D3 of the third extension section 41 in the first direction X is greater than a size D4 of the fourth extension section 42 in the first direction X, which facilitates the transmission of current from the first power auxiliary line 501 to the first power bus VSS2. In addition, it may be possible to reduce the current density at the connection position between the first power auxiliary line 501 and the first power bus VSS2, reduce the risk of connection failure (such as breakage) at the connection between the first power auxiliary line 501 and the first power bus VSS2, and improve the connection reliability between the first power auxiliary line 501 and the first power bus VSS2. FIG. 19 is a partial enlarged view of first power auxiliary lines according to some embodiments.

It will be understood that other power auxiliary lines 50 (such as the second power auxiliary line 502 and the third power auxiliary line 503) may all have the structure as shown in FIG. 19. That is, other power auxiliary lines 50 may also include a third extension section 41 and a fourth extension section 42. In this way, the connection reliability between all power auxiliary lines 50 and the first power bus VSS2 may be improved.

In some embodiments, the size of the third extension section 41 in the first direction X is D3, the size of the fourth extension section 42 in the first direction X is D4, and D3 and D4 satisfy: D3=(2˜5)×D4. That is, in the first direction X, the size of the third extension section 41 is 2 to 5 times the size of the fourth extension section 42. For example, the size of the third extension section 41 is 2 times, 2.5 times, 4 times, 5 times, etc. the size of the fourth extension section 42.

In some embodiments, as shown in FIG. 18, the plurality of power auxiliary lines 50 further include a plurality of third power auxiliary lines 503, and the plurality of third power auxiliary lines 503 are located on a side of the first region 101 away from the edge region AA1 of the display region AA in the first direction X. In other words, the plurality of third power auxiliary lines 503 are closer to the central region AA2 of the display region AA in the first direction X than the first region 101.

As shown in FIG. 18, the display panel 1100 may further include a second power bus VDD1 and a second power fan-out line VDD2. The second power bus VDD1 extends in the first direction X and is closer to the display region AA than the second power fan-out line VDD2. The second power bus VDD1 is configured to be electrically connected to the pixel circuits in the display region AA and transmit a second voltage signal to the pixel circuits. The second power fan-out line VDD2 is configured to lead the second power bus VDD1 out to the fan-out region so as to be bonded and connected to the FPC, and electrically connected to the driver circuit board through the FPC.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, having a display region and a fan-out region, the fan-out region being adjacent to an edge of the display region; the display panel comprising:
a plurality of data lines arranged at intervals in a first direction and extending in a second direction, the first direction and the second direction intersecting, wherein the plurality of data lines include a plurality of first data lines and a plurality of second data lines, the plurality of first data lines are located in two edge regions of the display region in the first direction, and the plurality of second data lines are located in a central region of the display region in the first direction;
a plurality of first connection lines extending in the first direction, wherein a first end of a first connection line is connected to a first data line, and a second end of the first connection line extends to the central region of the display region in the first direction;
a plurality of second connection lines extending in the second direction, wherein a first end of a second connection line is connected to the second end of the first connection line, and a second end of the second connection line extends to an edge of the display region close to the fan-out region;
a plurality of first power auxiliary lines located on a side of the plurality of second connection lines close to the plurality of first data lines, wherein the plurality of first power auxiliary lines are arranged at intervals in the first direction, and the plurality of first power auxiliary lines extend in the second direction;
a first power bus extending in the first direction and being connected to the plurality of first power auxiliary lines; and
a first power fan-out line located on a side of the first power bus away from the display region, wherein the first power fan-out line includes a contact portion, the contact portion is in contact with and connected to the first power bus, and the contact portion includes a first sidewall close to an edge region of the display region in the first direction;
wherein a first power auxiliary line includes at least one current confluence point connected to the first power bus; in the first direction, the at least one current confluence point is closer to the central region of the display region in the first direction than the first sidewall.

2. The display panel according to claim 1, wherein
the first power auxiliary line includes a current confluence point connected to the first power bus, and an end of the first power auxiliary line close to the fan-out region is electrically connected to the first power bus to form the current confluence point;
the first power bus includes a first extension section and a second extension section; in the second direction, the first extension section is arranged opposite to a region where the plurality of first power auxiliary lines are located, and the second extension section is arranged opposite to a region where at least part of the plurality of second connection lines are located;
at least part of the contact portion is in contact with and connected to the first extension section.

3. The display panel according to claim 2, wherein the contact portion includes:
a first sub-portion, wherein the first sub-portion is in contact with and connected to the second extension section, and the first sub-portion and the first extension section are spaced apart; and
a second sub-portion, wherein the second sub-portion and the first sub-portion are spaced apart in the first direction, and the second sub-portion is located on a side of the first sub-portion away from the central region of the display region in the first direction; a part of the second sub-portion is in contact with and connected to the first extension section, and another part of the second sub-portion is in contact with and connected to the second extension section.

4. The display panel according to claim 2, wherein the contact portion includes:
a first sub-portion, wherein the first sub-portion is in contact with and connected to the second extension section, and the first sub-portion and the first extension section are spaced apart; and
a second sub-portion, wherein the second sub-portion and the first sub-portion are spaced apart in the first direction, and the second sub-portion is located on a side of the first sub-portion away from the central region of the display region in the first direction; and the second sub-portion is in contact with and connected to the first extension section.

5. The display panel according to claim 4, wherein a sidewall of the second sub-portion close to the first sub-portion is flush with a first reference line, or is located on a side of the first reference line away from the second sub-portion; wherein the first reference line coincides with one of the plurality of first power auxiliary lines that is closest to the central region of the display region in the first direction.

6. The display panel according to claim 2, wherein the contact portion includes:
a first sub-portion, wherein a part of the first sub-portion is in contact with and connected to the first extension section, and another part of the first sub-portion is in contact with and connected to the second extension section; and
a second sub-portion, wherein the second sub-portion and the first sub-portion are spaced apart in the first direction, and the second sub-portion is located on a side of the first sub-portion away from the central region of the display region in the first direction; and the second sub-portion is in contact with and connected to the first extension section.

7. The display panel according to claim 2, wherein the contact portion includes:
a first sub-portion in contact with and connected to the first extension section; and
a second sub-portion, wherein the second sub-portion and the first sub-portion are spaced apart in the first direction, and the second sub-portion is located on a side of the first sub-portion away from the central region of the display region in the first direction; and the second sub-portion is in contact with and connected to the first extension section.

8. The display panel according to claim 7, wherein a sidewall of the first sub-portion close to the central region of the display region in the first direction is flush with a first reference line, or is located on a side of the first reference line away from the central region of the display region in the first direction; wherein the first reference line coincides with one of the plurality of first power auxiliary lines that is closest to the central region of the display region in the first direction.

9. The display panel according to claim 1, further comprising:
at least one second power auxiliary line extending in the second direction, wherein a second power auxiliary line is located between two adjacent second connection lines, and an end of the second power auxiliary line close to the fan-out region is connected to the first power bus; and
at least one third connection line extending in the first direction, wherein an end of a third connection line is connected to the first power auxiliary line, and another end of the third connection line is connected to a second power auxiliary line;
wherein an end of the first power auxiliary line close to the fan-out region is connected to the first power bus to form a current confluence point; and at least one first power auxiliary line is connected to the first power bus through a third connection line and a second power auxiliary line in sequence, to form a current confluence point.

10. The display panel according to claim 9, wherein
the first power bus includes a first extension section and a second extension section; in the second direction, the first extension section is arranged opposite to a region where the plurality of first power auxiliary lines are located, and the second extension section is arranged opposite to a region where the at least one second power auxiliary line and at least part of the plurality of second connection lines are located;
at least part of the contact portion is connected to the second extension section.

11. The display panel according to claim 10, wherein the contact portion is in contact with and connected to the second extension section; in the first direction, the first sidewall is closer to the central region of the display region in the first direction than the plurality of first power auxiliary lines;
the contact portion further includes a second sidewall close to the central region of the display region in the first direction; the second sidewall is flush with a second power auxiliary line closest to the central region of the display region in the first direction, or the second sidewall is closer to the first sidewall than the second power auxiliary line closest to the central region of the display region in the first direction.

12. The display panel according to claim 10, wherein the contact portion includes:
a first sub-portion, wherein at least part of the first sub-portion is in contact with and connected to the second extension section; and
a second sub-portion, wherein the second sub-portion and the first sub-portion are spaced apart in the first direction, the second sub-portion is located on a side of the first sub-portion away from the central region of the display region in the first direction, and at least part of the second sub-portion is in contact with and connected to the first extension section.

13. The display panel according to claim 9, wherein the display panel comprises a plurality of second power auxiliary lines; and a number of second connection lines arranged between two adjacent second power auxiliary lines is in a range of 2 to 7, inclusive.

14. The display panel according to claim 3, wherein
the first sub-portion and the second sub-portion extend in the second direction, and a first end of the first sub-portion and a first end of the second sub-portion are both connected to the first power bus;
the first power fan-out line further includes a bonding portion extending in the first direction, and two ends of the bonding portion are respectively connected to a second end of the first sub-portion and a second end of the second sub-portion.

15. The display panel according to claim 14, wherein
a size of the second sub-portion in the first direction is greater than a size of the first sub-portion in the first direction.

16. The display panel according to claim 15, wherein
the size of the first sub-portion in the first direction is D1;
the size of the second sub-portion in the first direction is D2; and
D1 and D2 satisfy: D2=(1.2˜4)×D1.

17. The display panel according to claim 1, wherein the first power auxiliary line includes:
a third extension section connected to the first power bus; and
a fourth extension section located on a side of the third extension section away from the fan-out region and connected to the third extension section;
wherein a size of the third extension section in the first direction is greater than a size of the fourth extension section in the first direction.

18. The display panel according to claim 17, wherein
the size of the third extension section in the first direction is D3;
the size of the fourth extension section in the first direction is D4; and
D3 and D4 satisfy: D3=(2˜5)×D4.

19. The display panel according to claim 1, wherein the first power bus includes:
a first sub-line extending along a border of the fan-out region close to the display region and being electrically connected to the plurality of first power auxiliary lines; and
two second sub-lines at least partially located on a side of the first sub-line away from the display region and electrically connected to the first sub-line, wherein the two second sub-lines are spaced apart in the first direction; the two second sub-lines are respectively located in two edge regions of the fan-out region in the first direction; and a second sub-line is electrically connected to the first power fan-out line.

20. A display apparatus, comprising:
the display panel according to claim 1; and
a driver circuit board configured to transmit control signals to the display panel.
